(19) United States
(12) Patent Application Publication
(10) Pub. No.: US 2026/0362714 A1
(43) Pub. Date: Nov. 12, 2026

(54) SEMICONDUCTOR DEVICE

(71) Applicant: INSTITUTE OF SCIENCE TOKYO, Tokyo (JP)

(72) Inventors: Norio CHUJO, Tokyo (JP); Takayuki OHBA, Tokyo (JP); Takashi YODA, Tokyo (JP)

(21) Appl. No.: 19/664,026

(22) Filed: Apr. 30, 2026

(30) Foreign Application Priority Data
May 9, 2025 (JP) 2025-078958

(51) Int. Cl. H10B 80/00; H10W 90/20; H10W 95/00

(52) U.S. Cl. CPC H10B 80/00; H10W 90/297; H10W 95/00

(57) ABSTRACT

A semiconductor device includes a stacked structure including stacked memory chips, a logic chip disposed above the stacked structure and configured to transmit signals to and receive signals from the memory chips, a first through electrode to supply electric power to the logic chip, the first through electrode penetrating the stacked structure and being electrically connected to the logic chip, and at least one of a first layer or a second layer disposed between the stacked structure and the logic chip, wherein the first layer is connected between the first through electrode and the logic chip, and includes a first circuit including a capacitive element to smooth voltage supplied to the logic chip via the first through electrode, and wherein the second layer is connected between the first through electrode and the logic chip, and includes a second circuit including a step-down circuit to step down the voltage.

### CROSS-REFERENCE TO RELATED APPLICATION

The present application is based on and claims priority to Japanese patent application No. 2025-078958 filed on May 9, 2025, with the Japan Patent Office, the entire contents of which are hereby incorporated by reference.

### BACKGROUND OF THE INVENTION

The disclosures herein relate to semiconductor devices.

Patent Literature (PTL) 1 discloses an electronic package including a chip stack including a plurality of memory chips, a logic chip (calculation die) arranged on the chip stack and electrically coupled to the plurality of memory chips, and a mold layer covering the chip stack and the logic chip. PTL 1 shows a configuration in which power is supplied to the logic chip via a through via passing through the memory chips. PTL 1 also shows a configuration in which power is supplied to the logic chip via a through via passing through a mold layer outside the chip stack.

However, the through via provided for supplying power to the logic chip is not involved in an operation of the memory chips. Therefore, as the number of through vias passing through the memory chips among through vias provided for supplying power to the logic chip increases, the storage capacity of the memory chips decreases.

Increasing the size of the memory chip to increase storage capacity increases cost. In addition, reducing the number of through vias passing through the memory chips in order to increase storage capacity reduces the total number of through vias provided for supplying power to the logic chip, thereby increasing the impedance in a power supply path to the logic chip, due to parasitic resistance, inductance, and capacitance. Therefore, an increase in voltage drop and voltage fluctuation may prevent the voltage required for operation of the logic chip from being ensured, resulting in operational errors.

The present disclosure aims to provide a semiconductor device that increases the storage capacity of a memory chip while ensuring a voltage required for the operation of a logic chip.

### CITATION LIST

### Patent Literature

PTL 1 Japanese Laid-open Patent Publication No. 2021-197541

### SUMMARY OF THE INVENTION

A semiconductor device includes a stacked structure including a plurality of stacked memory chips, a logic chip disposed above the stacked structure and configured to transmit signals to and receive signals from the plurality of memory chips, a first through electrode configured to supply electric power to the logic chip, the first through electrode penetrating the stacked structure and being electrically connected to the logic chip, and at least one of a first layer or a second layer disposed between the stacked structure and the logic chip, wherein the first layer, when present, is connected between the first through electrode and the logic chip, and includes a first circuit including a capacitive element configured to smooth voltage supplied to the logic chip via the first through electrode, and wherein the second layer, when present, is connected between the first through electrode and the logic chip, and includes a second circuit including a step-down circuit configured to step down the voltage.

According to the present disclosure, a semiconductor device that increases the storage capacity of a memory chip while ensuring a voltage required for the operation of a logic chip is provided.

### BRIEF DESCRIPTION OF THE DRAWINGS

FIG. 1 is a plan view schematically illustrating a semiconductor device according to a first embodiment;

FIG. 2 is a cross-sectional view schematically illustrating the semiconductor device of FIG. 1 taken along a line II-II;

FIG. 3A is a schematic cross-sectional view illustrating an example of a method of manufacturing the semiconductor device according to the first embodiment;

FIG. 3B is a schematic cross-sectional view illustrating an example of the method of manufacturing the semiconductor device according to the first embodiment;

FIG. 3C is a schematic cross-sectional view illustrating an example of the method of manufacturing the semiconductor device according to the first embodiment;

FIG. 3D is a schematic cross-sectional view illustrating an example of the method of manufacturing the semiconductor device according to the first embodiment;

FIG. 3E is a schematic cross-sectional view illustrating an example of the method of manufacturing the semiconductor device according to the first embodiment;

FIG. 4A is a schematic cross-sectional view illustrating an example of the method of manufacturing the semiconductor device according to the first embodiment;

FIG. 4B is a schematic cross-sectional view illustrating an example of the method of manufacturing the semiconductor device according to the first embodiment;

FIG. 4C is a schematic cross-sectional view illustrating an example of the method of manufacturing the semiconductor device according to the first embodiment;

FIG. 4D is a schematic cross-sectional view illustrating an example of the method of manufacturing the semiconductor device according to the first embodiment;

FIG. 5A is a schematic cross-sectional view illustrating an example of the method of manufacturing the semiconductor device according to the first embodiment;

FIG. 5B is a schematic cross-sectional view illustrating an example of the method of manufacturing the semiconductor device according to the first embodiment;

FIG. 5C is a schematic cross-sectional view illustrating an example of the method of manufacturing the semiconductor device according to the first embodiment;

FIG. 6 is a schematic cross-sectional view illustrating an example of the method of manufacturing the semiconductor device according to the first embodiment;

FIG. 7 is a schematic cross-sectional view illustrating an example of the method of manufacturing the semiconductor device according to the first embodiment;

FIG. 8 is a schematic cross-sectional view illustrating an example of the method of manufacturing the semiconductor device according to the first embodiment; and

FIG. 9 is a cross-sectional view schematically illustrating a semiconductor device according to a second embodiment.

### DESCRIPTION OF THE PREFERRED EMBODIMENTS

In the following, embodiments of the present invention will be described with reference to the accompanying drawings. The embodiments described below are only an example, and the embodiments to which the present invention is applied are not limited to the following embodiments.

In the following drawings, directions may be indicated by an X-axis, a Y-axis, and a Z-axis. The X-axis, the Y-axis, and the Z-axis extend in mutually orthogonal directions. A direction in which an arrow is directed in the X-axis direction may be referred to as a +X direction, and a direction opposite to the +X direction may be referred to as a -X direction. Further, a direction in which an arrow is directed in the Y-axis direction may be referred to as a +Y direction, and a direction opposite to the +Y direction may be referred to as a -Y direction. Further, a direction in which an arrow is directed in the Z-axis direction may be referred to as a +Z direction, and a direction opposite to the +Z direction may be referred to as a -Z direction. In the illustrated example, the +Z direction refers to as an upward direction. Further, the -Z direction refers to a downward direction. However, these do not limit the direction in which the semiconductor device according to the embodiments is used.

### FIRST EMBODIMENT

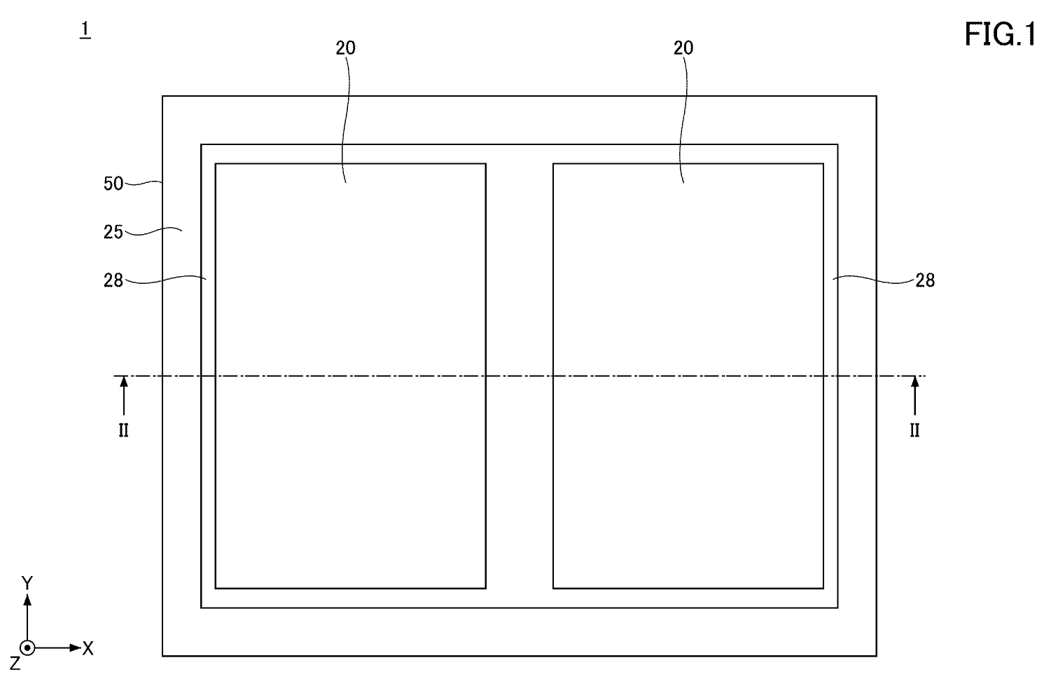

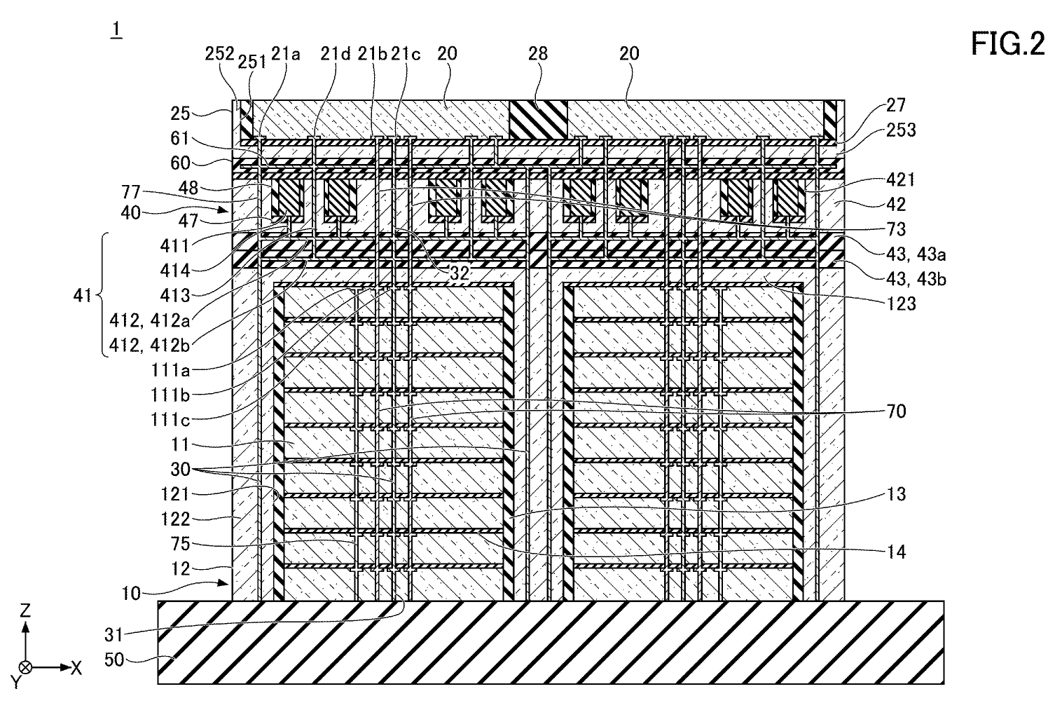

A configuration example of a semiconductor device 1 according to a first embodiment will be described with reference to FIGS. 1 and 2. FIG. 1 is a plan view schematically illustrating the semiconductor device 1 according to the first embodiment. FIG. 2 is a cross-sectional view schematically illustrating the semiconductor device 1 of FIG. 1 taken along a line II-II.

As shown in FIGS. 1 and 2, the semiconductor device 1 includes a stacked structure 10, a logic chip 20, a first through electrode 30, and a first layer 40. The semiconductor device 1 may further include a substrate 50, a layer 60, a second through electrode 70, a third through electrode 73, and a fourth through electrode 75. For convenience of explanation, the layer 60 will hereinafter be referred to as a “third layer 60”.

### STACKED STRUCTURE 10

The stacked structure 10 includes a plurality of memory chips 11 stacked in the Z-axis direction. The stacked structure 10 may further include a first support substrate 12. In the example shown in FIG. 2, the plurality of memory chips 11 are disposed in a recess 121 of the first support substrate 12 while being fixed with a resin member 13. However, the stacked structure 10 need not include the first support substrate 12.

In the example shown in FIG. 2, vertically adjacent memory chips 11 are bonded to each other via an adhesive layer 14. Note that the vertically adjacent memory chips 11 may be directly bonded without the adhesive layer 14. Further, a connection member such as a microbump may be arranged between the vertically adjacent memory chips 11. In the example shown in FIG. 2, nine layers of memory chips 11 are stacked in the Z-axis direction. However, the number of memory chips 11 to be stacked is not limited to the example shown in FIG. 2.

The memory chips 11 include memory cells for storing various types of data to be processed in the logic chip 20. Examples of the memory chips 11 include DRAM (Dynamic Random Access Memory), SRAM (Static Random Access Memory), and NAND flash memory. However, a configuration of the memory chips 11 is not limited to the above.

Each memory chip 11 can include, for example, a substrate, an integrated circuit disposed on the substrate, and an insulating layer disposed on the integrated circuit. The substrate includes, for example, a semiconductor material such as silicon (Si), gallium nitride (GaN), and silicon carbide (SiC). The integrated circuit includes semiconductor elements such as transistors that form the memory cells and peripheral circuits in the memory chips 11. The insulating layer includes an insulating material such as silicon oxide (SiO₂) and silicon nitride (Si₃N₄).

Each memory chip 11 may further include electrode pads 111a, 111b, and 111c. The electrode pads 111a, 111b, and 111c are provided on the insulating layer of the memory chip 11, for example. The electrode pads 111a and 111b are electrically connected to the integrated circuit of the memory chip 11. The electrode pads 111a, 111b, and 111c include a metal material such as titanium (Ti), gold (Au), aluminum (Al), and copper (Cu), for example. Each of the electrode pads 111a, 111b, and 111c may have a single-layer structure or a stacked structure.

The first support substrate 12 supports a plurality of memory chips 11. As shown in FIG. 2, the first support substrate 12 includes the recess 121 and lateral walls 122 located outside the recess 121. A plurality of lateral walls 122 are provided so as to cover both lateral surfaces of the plurality of stacked memory chips 11. Further, the first support substrate 12 may further include an upper wall 123 connecting the +Z direction ends of the plurality of lateral walls 122 to each other. In the example shown in FIG. 2, the recess 121 is defined by an inner surface of the lateral walls 122 and a bottom surface of the upper wall 123.

In the example shown in FIG. 2, the recess 121 is open in the -Z direction. However, the recess 121 may be open in the +Z direction. When the recess 121 is open in the +Z direction, the first support substrate 12 may include a bottom wall connecting the -Z direction ends of the plurality of lateral walls 122. In this case, the first support substrate 12 need not include the upper wall 123.

The first support substrate 12 preferably includes an inorganic material containing silicon. Examples of the inorganic material containing silicon include silicon and silicon oxide. Since the first support substrate 12 includes the inorganic material containing silicon, a plurality of first through electrodes 30 can be easily and accurately formed on the lateral wall 122 of the first support substrate 12 compared with a case where the first support substrate 12 is made of, for example, a resin material. Thus, the number of the first through electrodes 30 penetrating the first support substrate 12 (the first through electrodes 30 disposed outside the memory chips 11) can be increased by a relatively simple processing step. As a result, the number of the first through electrodes 30 disposed in the memory chips 11 can be reduced while maintaining or increasing the total number of the first through electrodes 30. Therefore, the storage capacity of the memory chips 11 can be increased while ensuring a voltage necessary for the operation of the logic chip 20.

### LOGIC CHIP 20

As shown in FIG. 2, the logic chip 20 is disposed on a +Z direction side of the stacked structure 10. The logic chip 20 transmits signals to and receive signals from the plurality of memory chips 11. That is, the logic chip 20 is communicatively connected to each of the plurality of memory chips 11. The logic chip 20 executes, for example, arithmetic processing using various data stored in the memory chips 11. In the example shown in FIG. 2, the logic chip 20 is electrically connected to the integrated circuit of each memory chip 11 via the second through electrode 70 and the third through electrode 73.

Examples of the logic chip 20 include chips corresponding to processors such as CPU (Central Processing Unit), GPU (Graphics Processing Unit), NPU (Neural Network Processing Unit), and TPU (Tensor Processing Unit), and chips including electronic circuits having arithmetic processing functions such as ASIC (Application Specific Integrated Circuit) and FPGA (Field Programmable Gate Array). However, a configuration of the logic chip 20 is not limited to the above.

Like the memory chip 11, the logic chip 20 may include a base material, an integrated circuit arranged on the base material, and an insulating layer arranged on the integrated circuit. The integrated circuit of the logic chip 20 includes arithmetic processing circuits including semiconductor elements such as transistors, and peripheral circuits. The arithmetic processing circuits of the logic chip 20 execute the aforementioned arithmetic processing. The base material and insulating layer of the logic chip 20 may have a configuration similar to that of the base material and insulating layer of the memory chip 11.

The logic chip 20 may further include electrode pads 21a, 21b, and 21c. The logic chip 20 may also include other electrode pads such as electrode pad 21d. The electrode pads 21a, 21b, and 21c are provided on the insulating layer of the logic chip 20, for example, and are electrically connected to the integrated circuit of the logic chip 20. In the example shown in FIG. 2, the electrode pad 21a is electrically connected to an external power supply via a first through electrode 30 disposed outside the memory chips 11. The electrode pad 21b is electrically connected to the electrode pad 111b of the memory chip 11 via the second through electrode 70 and the third through electrode 73. The electrode pad 21c is electrically connected to the first through electrode 30 disposed in the memory chips 11. The electrode pads 21a, 21b, and 21c can include the same metal material as the electrode pads 111a, 111b, and 111c.

The semiconductor device 1 is preferably provided with a second support substrate 25 for supporting the logic chip 20. As shown in FIG. 2, the second support substrate 25 may include a recess 251 open in the +Z direction for arranging the logic chip 20, a lateral wall 252 located outside the recess 251, and a bottom wall 253. In the example shown in FIG. 2, the logic chip 20 is disposed in the recess 251 while being fixed by an adhesive layer 27 and a resin member 28. Thus, the logic chip 20 can be firmly fixed at a desired position. Like the first support substrate 12, the second support substrate 25 may include an inorganic material containing silicon.

### FIRST THROUGH ELECTRODE 30

The first through electrode 30 penetrates the stacked structure 10 in the Z-axis direction. The first through electrode 30 is a through electrode provided for supplying power to the logic chip 20. The first through electrode 30 is electrically connected to the logic chip 20. The first through electrode 30 is part of a power supply path between the external power source and the logic chip 20.

In the example shown in FIG. 2, a first through electrode 30 disposed outside the memory chips 11 and a first through electrode 30 disposed inside the memory chips 11 are provided, respectively. Each of the first through electrodes 30 may include a via hole and a conductive member filled in the via hole. The conductive member of the first through electrode 30 includes, for example, the same metal material as the electrode pads 111a, 111b, and 111c. However, a configuration of the first through electrode 30 is not limited to the example shown in FIG. 2.

The first through electrode 30 disposed outside the memory chips 11 penetrates, for example, the lateral wall 122 of the first support substrate 12 in the Z-axis direction. Additionally, the first through electrode 30 disposed in the memory chips 11 includes a plurality of first portions 31 each penetrating a corresponding memory chip 11, and a second portion 32 extending from the uppermost memory chip 11 in the +Z direction to the logic chip 20. In the first through electrode 30 disposed in the memory chips 11, each of the first portions 31 electrically connects electrode pads 111c of the vertically adjacent memory chips 11. The second portion 32 electrically connects electrode pads 111c of an uppermost memory chip 11 in the +Z direction to electrode pads 21c of the logic chip 20.

Here, a position of the first through electrodes 30 is not limited to the example shown in FIG. 2. For example, all of the first through electrodes 30 may be disposed so as to penetrate the lateral walls 122 of the first support substrate 12. In this case, the semiconductor device 1 does not include the first through electrodes 30 disposed in the memory chips 11. Thus, all of the first through electrodes 30 provided for supplying power to the logic chip 20 can be disposed outside the memory chips 11. As a result, a region corresponding to the memory cell of the memory chips 11 can be increased, and the storage capacity of the memory chips 11 can be increased.

### SECOND THROUGH ELECTRODES 70 AND THIRD THROUGH ELECTRODE 73

The second through electrodes 70 and the third through electrodes 73 are through electrodes forming at least part of a signal line between the plurality of memory chips 11 included in the stacked structure 10 and the logic chip 20. The memory chips 11 and the logic chip 20 are electrically connected by the second through electrodes 70 and the third through electrodes 73. In the example shown in FIG. 2, a plurality of second through electrodes 70 penetrating each of the memory chips 11 are provided. Each of the second through electrodes 70 electrically connects electrode pads 111b of the vertically adjacent memory chips 11.

The third through electrode 73 is electrically connected to the second through electrode 70, and is also electrically connected to the logic chip 20 through the second support substrate 25. In the example shown in FIG. 2, the third through electrode 73 is electrically connected to the second through electrode 70 through the electrode pad 111b of the uppermost memory chip 11 in the +Z direction. The third through electrode 73 is also electrically connected to the electrode pad 21b of the logic chip 20 through the bottom wall 253 of the second support substrate 25 in the Z-axis direction. By electrically connecting the memory chips 11 and the logic chip 20 through the third through electrode 73 penetrating the second support substrate 25 in the Z-axis direction, the signal line can be shortened. As a result, a transmission speed of signals transmitted to and received from the memory chips 11 and the logic chip 20 can be improved.

### FOURTH THROUGH ELECTRODE 75

The fourth through electrode 75 is a through electrode provided for supplying power to the memory chips 11. In the example shown in FIG. 2, a plurality of fourth through electrodes 75 penetrating through the respective memory chips 11 are provided. The fourth through electrodes 75 electrically connect the electrode pads 111a of the vertically adjacent memory chips 11.

### FIRST LAYER 40

The first layer 40 may include a first circuit 41. As shown in FIG. 2, the first circuit 41 is connected between the first through electrodes 30 and the logic chip 20. In the present specification, “an object A is connected between an object B and an object C” means that an object A is electrically connected to both an object B and an object C.

The first layer 40 is disposed between the stacked structure 10 and the logic chip 20 in the Z-axis direction. The first layer 40 may further include a third support substrate 42 for supporting a capacitive element 411 included in the first circuit 41, which will be described later. Like the first support substrate 12 and the second support substrate 25, the third support substrate 42 can include an inorganic material containing silicon.

In the stacked structure 10, conductive members such as interconnects included in the integrated circuit of each memory chip 11, the first through electrode 30, the second through electrode 70, and the fourth through electrode 75 are arranged at a high density. Therefore, there is a possibility that the voltage supplied to the logic chip 20 through the first through electrode 30 may increase or decrease (fluctuate) over time due to parasitic components such as parasitic inductance and parasitic capacitance generated in the stacked structure 10. Here, if the number of the first through electrodes 30 arranged in the memory chips 11 is reduced in order to increase the storage capacity of the memory chips 11, the voltage supplied to the logic chip 20 becomes low, and when the voltage temporarily decreases, there is a possibility that a voltage necessary for the operation of the logic chip 20 cannot be ensured, causing problems such as errors in operation. For convenience of explanation, the voltage supplied to the logic chip 20 through the first through electrode 30 may be referred to as a “first voltage”.

The first circuit 41 includes the capacitive element 411 for smoothing the first voltage supplied to the logic chip 20. Since the first circuit 41 includes the capacitive element 411, it is possible to prevent the first voltage supplied to the logic chip 20 from increasing or decreasing over time. This suppresses a temporary decrease in the first voltage thereby preventing a state in which a voltage required for operation of the logic chip 20 cannot be ensured. That is, even if the number of the first through electrodes 30 disposed in the memory chips 11 among the first through electrodes 30 provided for supplying power to the logic chip 20 is reduced, the possibility that the voltage required for the operation of the logic chip 20 cannot be ensured can be reduced. Therefore, according to the present embodiment, the storage capacity of the memory chips 11 can be increased while ensuring the voltage value required for the operation of the logic chip 20.

The capacitive element 411 is, for example, a multilayer ceramic capacitor or a silicon capacitor. The capacitive element 411 may be a capacitor having a configuration different from that of the multilayer ceramic capacitor or the silicon capacitor.

In the example shown in FIG. 2, the capacitive element 411 is disposed in recess 421 of the third support substrate 42 while being fixed by an adhesive layer 47 and a resin member 48. Thus, the capacitive element 411 can be firmly fixed at a desired position. However, the position of the capacitive element 411 is not limited to the above.

The first circuit 41 may further include a plurality of first interconnects 412 (412a, 412b). The plurality of first interconnects 412 can electrically connect the first through electrode 30 and the logic chip 20. Specifically, the first voltage from the first through electrode 30 can be distributed in the X-axis direction and Y-axis direction via the plurality of first interconnects 412 and supplied to the logic chip 20. In the example shown in FIG. 2, each of the plurality of first interconnects 412 is electrically connected to the electrode pad 21d of the logic chip 20 via a fifth through electrode 413 penetrating the third support substrate 42 in the Z-axis direction.

By electrically connecting the first through electrode 30 and the logic chip 20 via the plurality of first interconnects 412, the number of power supply paths from the first circuit 41 to the logic chip 20 can be increased. As a result, resistance (including impedance) in the power supply paths to the logic chip 20 in the X-axis direction and Y-axis direction can be reduced as compared with the case where the first voltage is supplied to the logic chip 20 only by the first through electrode 30. As a result, the voltage drop of the first voltage of the logic chip 20 supplied from the first through electrode 30 can be reduced, and the possibility that the voltage required for the operation of the logic chip 20 cannot be ensured can be further reduced. Furthermore, by electrically connecting the first through electrode 30 and the logic chip 20 via the fifth through electrode 413, the resistance in the power supply paths can be further reduced. Furthermore, the first through electrode 30 and the logic chip 20 may be electrically connected by the first interconnects 412a and 412b and the interconnects in the plurality of redistribution layers. Thus, the resistance in the power supply path in the X-axis direction and the Y-axis direction can be further reduced.

In the example shown in FIG. 2, two first interconnects 412a and 412b are provided. The first interconnects 412a and 412b can be arranged in redistribution layers 43 (43a, 43b) located on the -Z direction side of the third support substrate 42. However, the number of the first interconnects 412 may be 3 or more.

At least one of the plurality of first interconnects 412 is electrically connected to the capacitive element 411. In the example shown in FIG. 2, the first interconnects 412a of the plurality of first interconnects 412 are electrically connected to the capacitive element 411 from the first interconnects 412a via a sixth through electrode 414. The capacitive element 411 is connected in parallel to the logic chip 20.

### SUBSTRATE 50

The substrate 50 is preferably disposed on the -Z direction side of the stacked structure 10. As shown in FIG. 2, with the substrate 50 disposed on the -Z direction side of the stacked structure 10, the logic chip 20 is separated from the substrate 50 via the stacked structure 10. In other words, the logic chip 20 is not interposed between the stacked structure 10 and the substrate 50 in the Z-axis direction. As a result, the upper surface of the logic chip 20, which generates more heat than the memory chip 11, can be exposed to the outside. As a result, heat generated in the logic chip 20 can be efficiently dissipated to the outside, and an excessive rise in a temperature of the logic chip 20 can be prevented.

The substrate 50 can include a first interconnect layer for electrically connecting the external power supply and the first through electrode 30. As a result, a first voltage can be supplied to the logic chip 20. The substrate 50 can further include a second interconnect layer for electrically connecting the external power supply and the fourth through electrode 75. Thus, a voltage for supplying power to each memory chip 11 can be supplied. The substrate 50 may include a semiconductor material such as silicon and gallium nitride, a ceramic material such as aluminum nitride and aluminum oxide, or an organic material such as epoxy. The substrate 50 may include another material.

### THIRD LAYER 60

The third layer 60 is disposed between the stacked structure 10 and the logic chip 20 in the Z-axis direction. As shown in FIG. 2, the third layer 60 is a redistribution layer including, for example, a third interconnect 61. The third interconnect 61 electrically connects the first through electrode 30 and the logic chip 20. In the example shown in FIG. 2, a seventh through electrode 77 extending from the first through electrode 30 is connected to the third interconnect 61. In the example shown in FIG. 2, the third interconnect 61 is electrically connected to the electrode pad 21d of the logic chip 20 via the fifth through electrode 413.

The first voltage from the external power supply is supplied to the third interconnect 61 through the first through electrode 30, the seventh through electrode 77, and the fifth through electrode 413. At this time, the first voltage is distributed in the X-axis direction and the Y-axis direction by the third interconnect 61 in addition to the first circuit 41 and supplied to the logic chip 20. This further reduces the possibility that the voltage required for the operation of the logic chip 20 cannot be ensured. As a result, the number of the first through electrodes 30 arranged in the memory chips 11 can be further reduced, and the storage capacity of the memory chips 11 can be further increased.

In addition to the through electrode shown in FIG. 2, another through electrode may be provided as the through electrode reaching the logic chip 20.

### MANUFACTURING METHOD OF FIRST EMBODIMENT

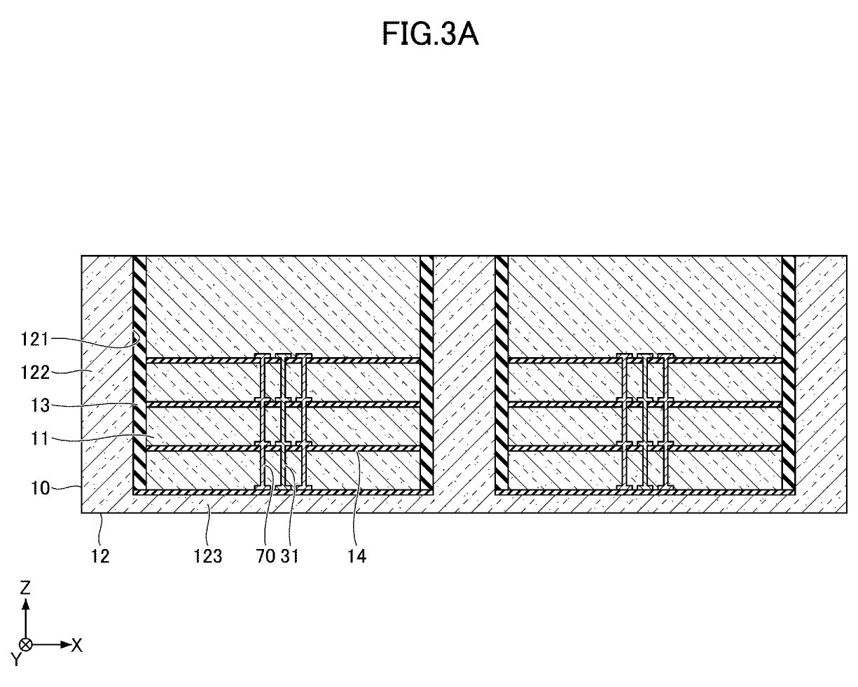

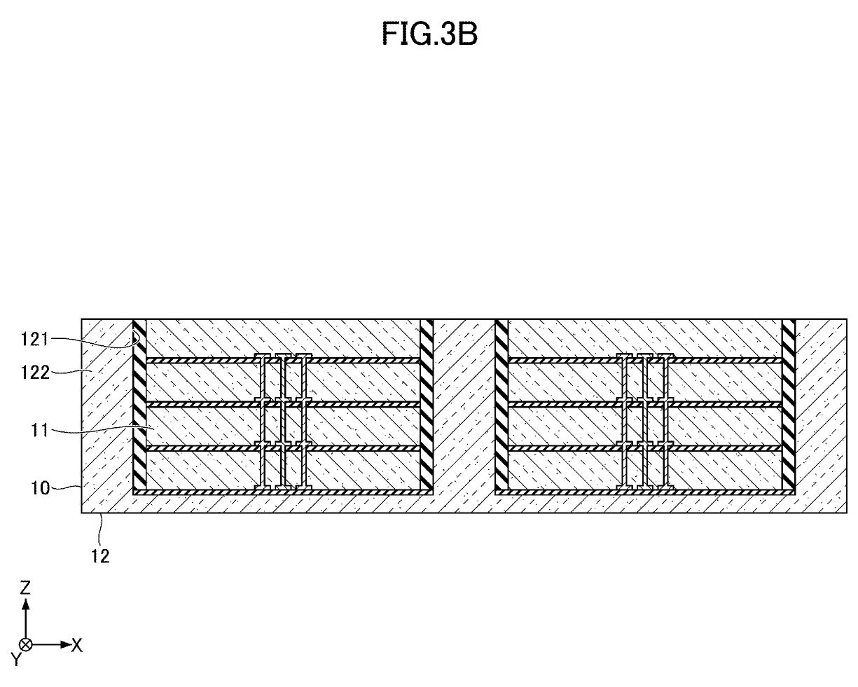

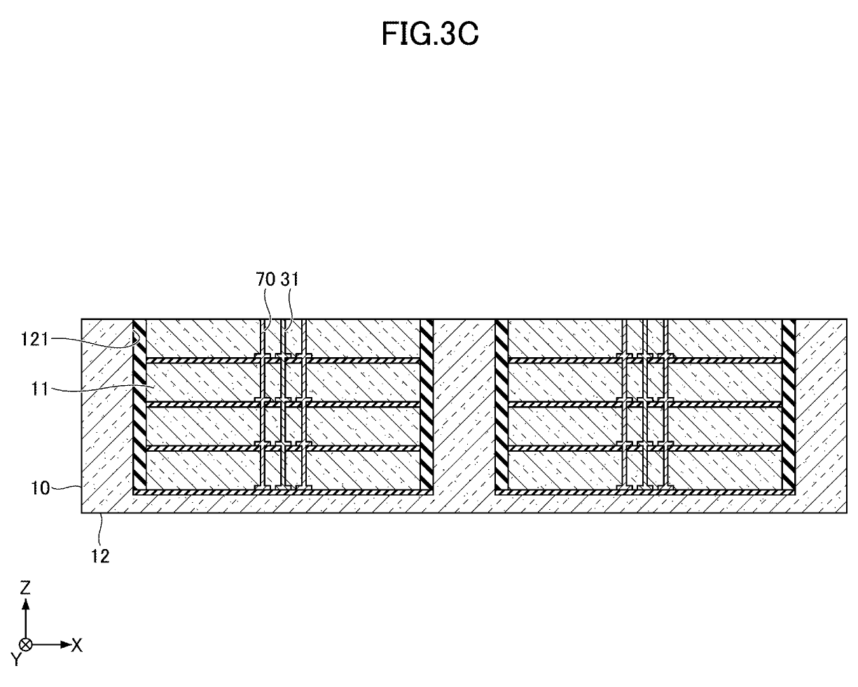

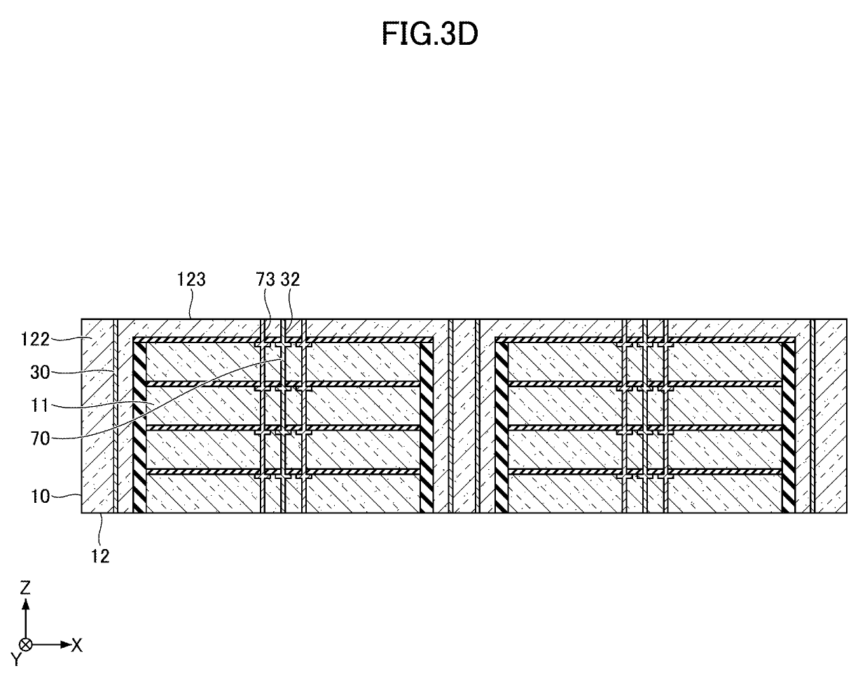

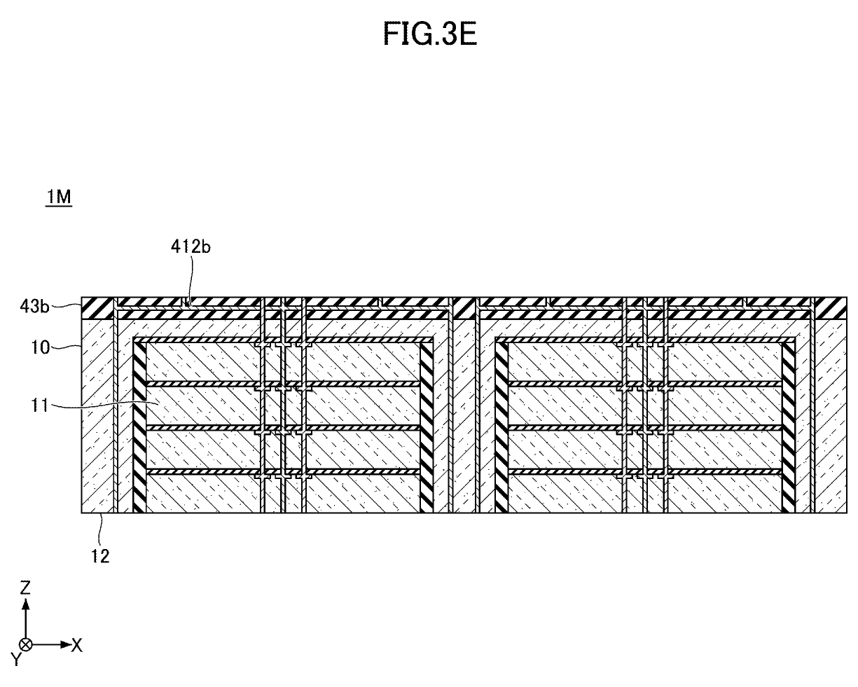

Next, an example of a method of manufacturing a semiconductor device according to the first embodiment will be described with reference to FIGS. 3A to 8. FIG. 3A to 8 are schematic cross-sectional views illustrating an example of the method of manufacturing the semiconductor device 1 according to the first embodiment. In FIGS. 3A to 8, the fourth through electrode 75 is omitted for convenience of explanation. For convenience of explanation, the number of memory chips 11 to be stacked shown in FIGS. 3A to 8 is smaller than the number of memory chips 11 shown in FIG. 2.

First, a structure 1M including the stacked structure 10 and the redistribution layer 43b, a structure 2M including the logic chip 20, the second support substrate 25, and the third layer 60, and a structure 3M including the capacitive element 411 and the third support substrate 42 are prepared.

An example of a step of preparing the structure 1M including the stacked structure 10 and the redistribution layer 43b will be described with reference to FIGS. 3A to 3E. As shown in FIG. 3A, a plurality of memory chips 11 and the resin member 13 stacked in the Z-axis direction are arranged in the recess 121 of the first support substrate 12, and the plurality of memory chips 11 are fixed in the recess 121. Thus, the stacked structure 10 is formed. The first portion 31 of the first through electrode 30 penetrating the memory chips 11 and the second through electrode 70 may be formed in advance in the memory chips 11.

Subsequently, as shown in FIG. 3B, the end of the memory chip 11 exposed from the recess 121 and the end of the lateral wall 122 of the first support substrate 12 are subjected to polishing or grinding to thin the stacked structure 10.

Subsequently, photolithography and etching are performed to form via holes penetrating the memory chips 11 exposed from the recess 121. Further, as shown in FIG. 3C, a conductive member is formed in the formed via holes by using an electroplating method. Thus, the first portion 31 and the second through electrode 70 penetrating the memory chips 11 exposed from the recess 121 of the first through electrode 30 are formed.

Subsequently, after the stacked structure 10 is turned upside down, photolithography and etching are performed to form via holes penetrating the lateral walls 122 and the upper wall 123 of the first support substrate 12. Further, as shown in FIG. 3D, a conductive member is formed in the formed via holes by using an electroplating method. Thus, a first through electrode 30 disposed outside the memory chips 11, part of the second portion 32 penetrating the upper wall 123, and part of the third through electrode 73 are formed.

Subsequently, as shown in FIG. 3E, an insulating layer serving as a base material for the redistribution layer 43b is formed on the stacked structure 10 by CVD (Chemical Vapor Deposition). Further, photolithography and etching are performed to form trenches and via holes in the insulating layer, and then conductive members such as the first interconnect 412b are formed in the trenches and via holes. Further, the upper surface of the insulating layer including the first interconnect 412b is polished. Thus, the redistribution layer 43b is formed.

By performing the steps of FIGS. 3A to 3E, the structure 1M including the stacked structure 10 and the redistribution layer 43b can be prepared.

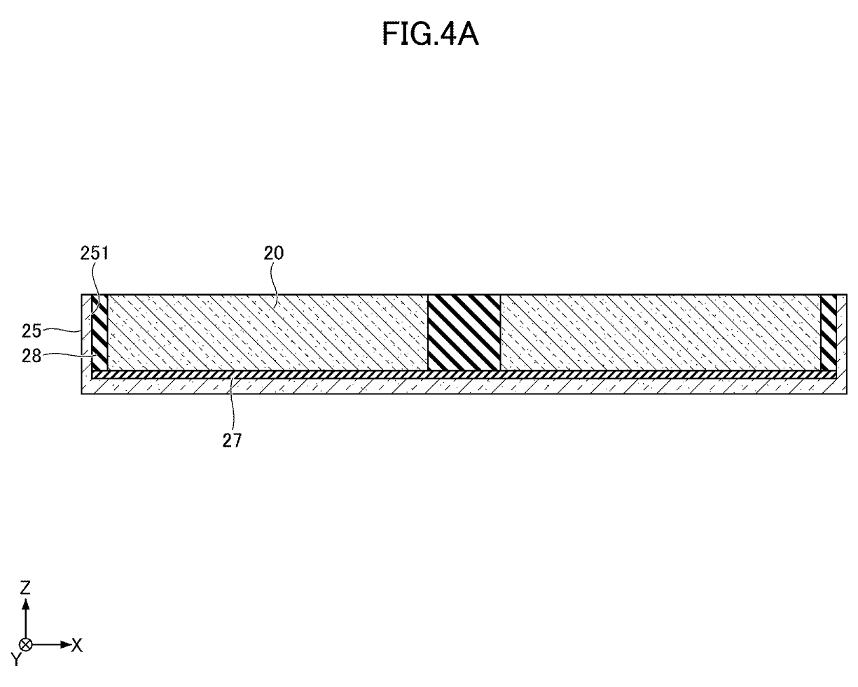

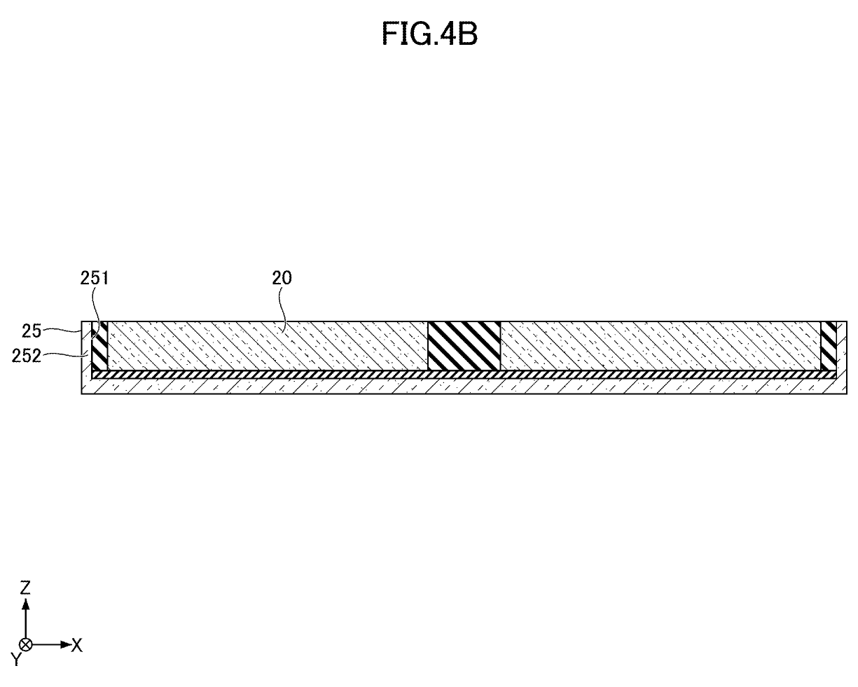

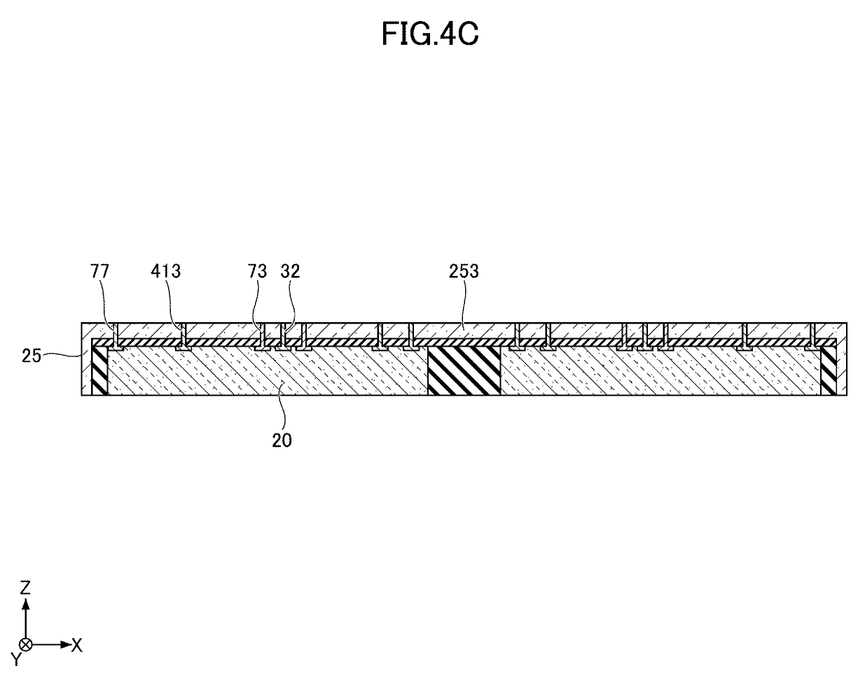

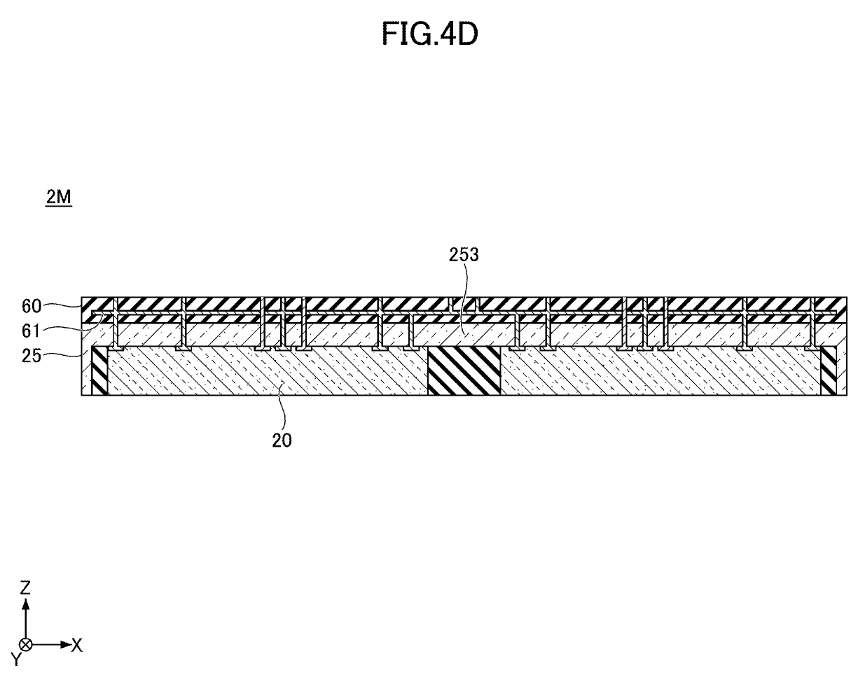

Next, an example of a step for preparing the structure 2M including the logic chip 20, the second support substrate 25, and the third layer 60 will be described with reference to FIGS. 4A to 4D. As shown in FIG. 4A, the logic chip 20, the adhesive layer 27, and the resin member 28 are arranged in the recess 251 of the second support substrate 25, and the logic chip 20 is fixed in the recess 251.

Subsequently, as shown in FIG. 4B, the end of the logic chip 20 exposed from the recess 251 and the end of the lateral wall 252 of the second support substrate 25 are subjected to polishing or grinding to thin the logic chip 20 and the second support substrate 25.

Subsequently, after the logic chip 20 and the second support substrate 25 are turned upside down, photolithography and etching are performed to form via holes penetrating the bottom wall 253 of the second support substrate 25. Further, as shown in FIG. 4C, an electroplating method is used to form conductive members in the formed via holes. Thus, part of the second portion 32 penetrating the bottom wall 253, part of the third through electrode 73, and part of the fifth through electrode 413 are formed.

Subsequently, as shown in FIG. 4D, a CVD (Chemical Vapor Deposition) method is used to form an insulating layer as a base material for the third layer 60 on the bottom wall 253 of the second support substrate 25. Further, photolithography and etching are performed to form trenches and via holes in the insulating layer, and then conductive members such as the third interconnect 61 are formed in the trenches and via holes. Further, the upper surface of the insulating layer is polished. Thus, the third layer 60 is formed.

By performing the steps of FIGS. 4A to 4D, the structure 2M including the logic chip 20, the second support substrate 25, and the third layer 60 can be prepared.

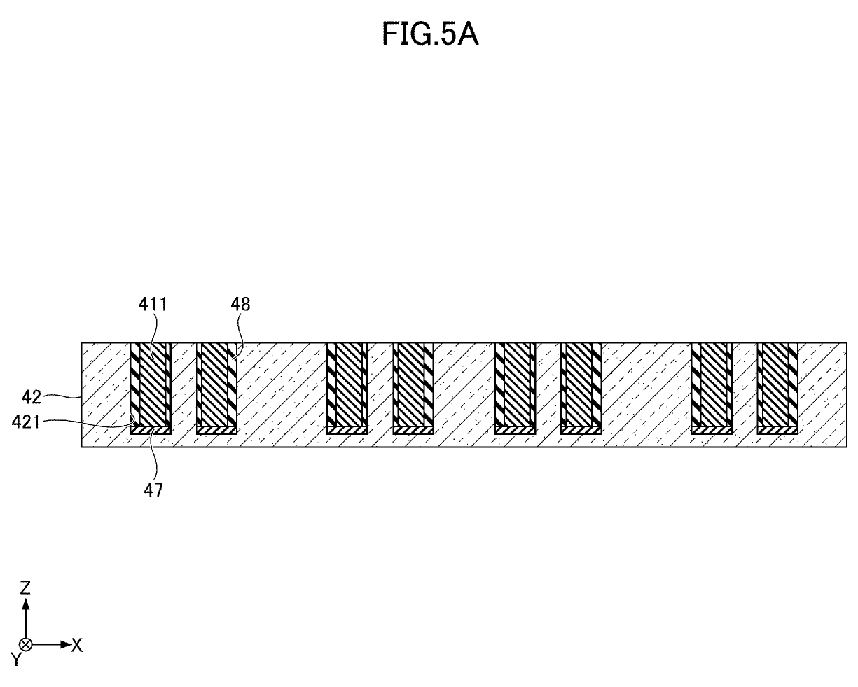

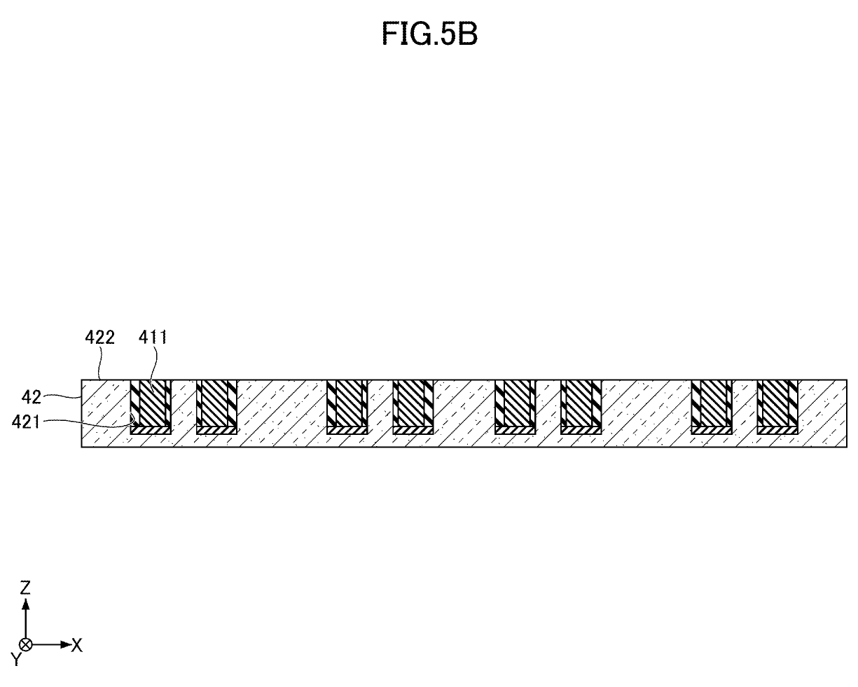

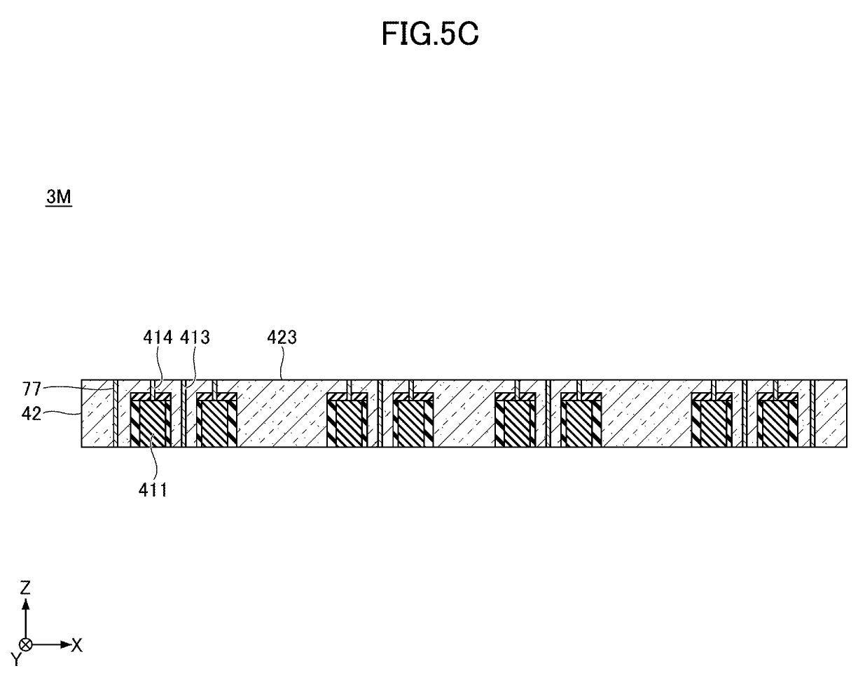

Next, referring to FIGS. 5A to 5C, an example of a step for preparing the structure 3M including the capacitive element 411 and the third support substrate 42 will be described. As shown in FIG. 5A, the capacitive element 411, the adhesive layer 47, and the resin member 48 are arranged in the recess 421 of the third support substrate 42, and the capacitive element 411 is fixed in the recess 421.

Subsequently, as shown in FIG. 5B, the end of the capacitive element 411 exposed from the recess 421 and the end of a lateral wall 422 of the third support substrate 42 are subjected to polishing or grinding to thin the capacitive element 411 and the third support substrate 42.

Subsequently, after the capacitive element 411 and the third support substrate 42 are turned upside down, photolithography and etching are performed to form a via hole penetrating the bottom wall 423 of the third support substrate 42. Further, as shown in FIG. 5C, a conductive member such as the sixth through electrode 414 is formed in the formed via hole by using an electroplating method. Thus, the sixth through electrode 414 is formed.

By performing the steps of FIGS. 5A to 5C, the structure 3M including the capacitive element 411 and the third support substrate 42 can be prepared. Note that the steps of preparing the structure 1M, the steps of preparing the structure 2M, and the steps of preparing the structure 3M may be performed at the same or different timings, respectively.

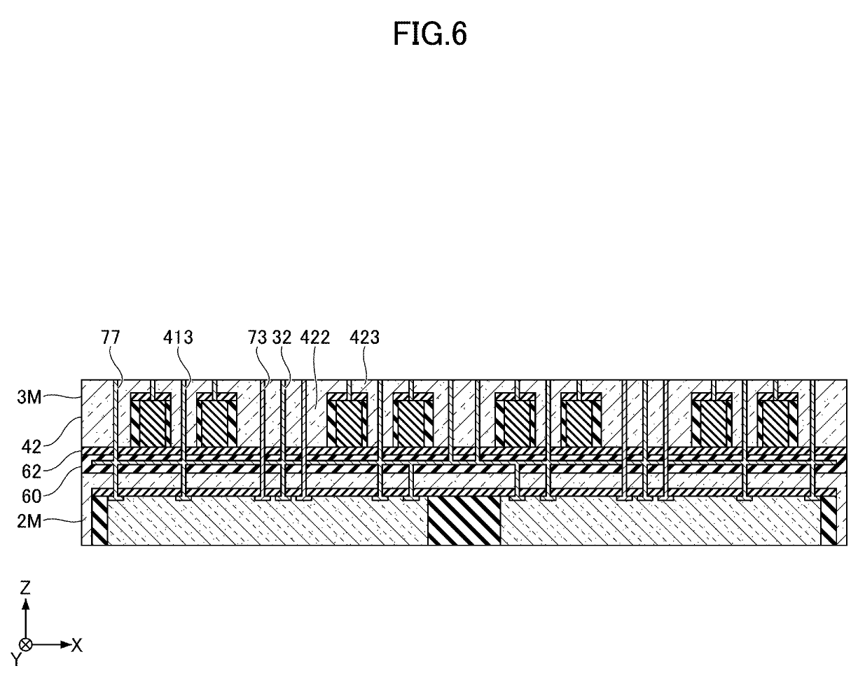

Next, as shown in FIG. 6, the third layer 60 of the structure 2M and the third support substrate 42 of the structure 3M are bonded. In the example shown in FIG. 6, the third layer 60 and the third support substrate 42 are bonded through an adhesive member 62. However, the third layer 60 and the third support substrate 42 may be directly bonded by fusion bonding or the like.

After bonding the third layer 60 and the third support substrate 42, photolithography and etching are performed to form via holes penetrating the third layer 60 and the lateral walls 422 and bottom walls 423 of the third support substrate 42. Electroplating is also used to form conductive members in the formed via holes. Thus, part of the second portion 32, part of the third through electrode 73, and part of the fifth through electrode 413 are formed.

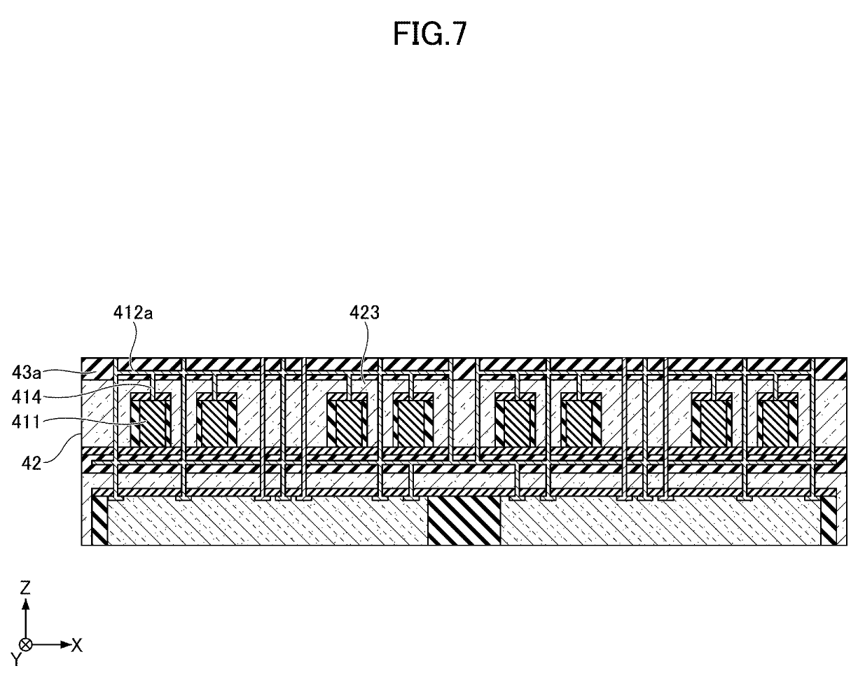

Next, as shown in FIG. 7, an insulating layer serving as a base material for the redistribution layer 43a is formed on the bottom wall 423 of the third support substrate 42 by CVD (Chemical Vapor Deposition). Photolithography and etching are also performed to form trenches and via holes in the insulating layer, and then conductive members such as the first interconnect 412a are formed in the trenches and via holes. At this time, the first interconnect 412a and the sixth through electrode 414 are electrically connected. That is, the first interconnect 412a and the capacitive element 411 are electrically connected. Further, a lower surface (in FIG. 7, a surface in the +Z direction) of the insulating layer including the first interconnect 412a is polished. Thus, the redistribution layer 43a is formed.

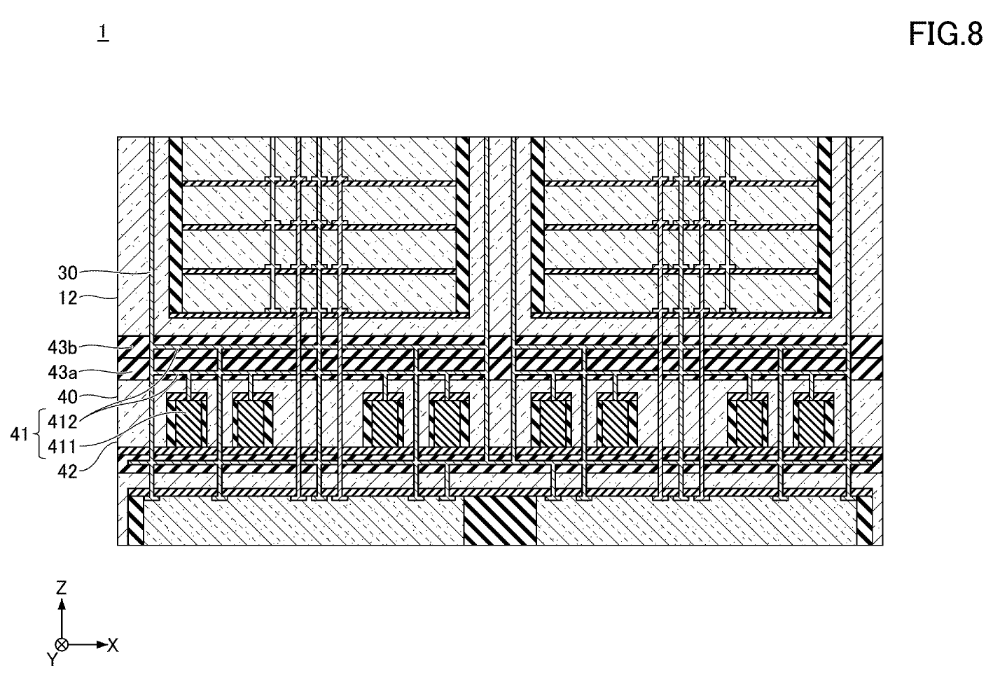

Next, as shown in FIG. 8, the substrates of the redistribution layers 43a and 43b are bonded to each other by, for example, fusion bonding to bond the first support substrate 12 and the third support substrate 42. Thus, the first layer 40 is formed. Furthermore, the structure after bonding is subjected to heat treatment to perform hybrid bonding. As a result, the conductive members in the via holes and trenches of the redistribution layers 43a and 43b expand and come into contact with each other, and are bonded by diffusion of metal atoms. As a result, the capacitive element 411 and the first interconnect 412 are electrically connected to form the first circuit 41. Further, the first circuit 41 and the first through electrode 30 are electrically connected. Thus, the semiconductor device 1 can be manufactured.

Further, after the first circuit 41 is formed, the structures 1M to 3M joined to each other can be arranged on the substrate 50. However, the semiconductor device 1 may be manufactured by omitting part of the steps shown in FIGS. 3A to 8 or by changing the steps to other steps. Further, the semiconductor device 1 may be manufactured by adding another step different from the steps shown in FIGS. 3A to 8.

In the present embodiment, the structures 1M, 2M, and 3M are prepared, and after bonding structures 2M and 3M, the resulting structure is bonded to structure 1M by fusion bonding and hybrid bonding involving heat treatment. However, the method of manufacturing the semiconductor device 1 is not limited thereto. For example, the semiconductor device 1 may be manufactured by stacking a plurality of memory wafers on which a plurality of memory circuits (circuits including memory cells) are formed in an in-plane direction on the structure 2M and the structure 3M bonded (e.g., a surface in the +Z direction in FIG. 7), and then dividing the wafers into individual pieces.

### SECOND EMBODIMENT

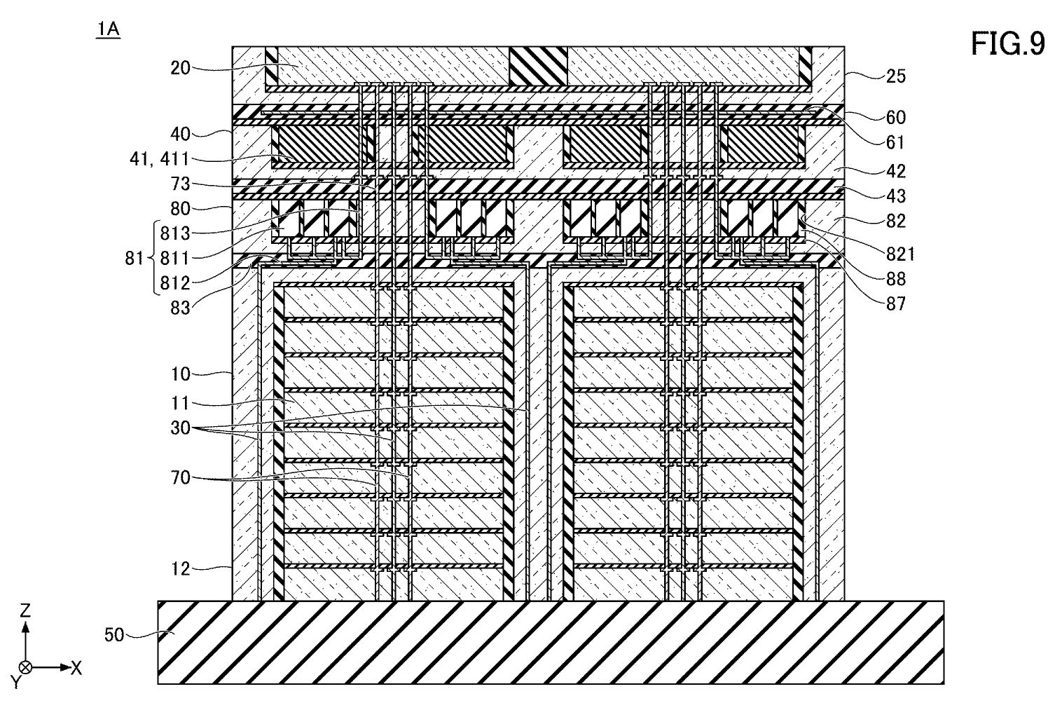

Next, a configuration example of a semiconductor device 1A according to the second embodiment will be described with reference to FIG. 9. FIG. 9 is a cross-sectional view schematically illustrating the semiconductor device 1A. In FIG. 9, the fourth through electrode 75 is omitted for convenience of explanation. Further, for convenience of explanation, among voltages supplied to the logic chip 20 through the first through electrode 30, a voltage supplied to the step-down circuit 811 described later through the first through electrode 30 may be referred to as a “second voltage”, and a voltage supplied from the step-down circuit 811 to the logic chip 20 may be referred to as a “first voltage”.

The semiconductor device 1A according to the second embodiment further includes a second layer 80. The second layer 80 is disposed, for example, between the stacked structure 10 and the first layer 40 in the Z-axis direction. Here, as shown in FIG. 9, the semiconductor device 1A preferably includes both the first layer 40 and the second layer 80. However, the semiconductor device 1A need not include the first layer 40 but may include the second layer 80.

The second layer 80 includes a second circuit 81 connected between the first through electrode 30 and the logic chip 20. In the example shown in FIG. 9, the second circuit 81 is connected between the first through electrode 30 and the first circuit 41.

As shown in FIG. 9, the second circuit 81 includes a step-down circuit 811 for stepping down the second voltage. The step-down circuit 811 includes a DC-DC converter circuit that is of a step-down type or a step-up/step-down type and includes elements such as a switching transistor, an inductor, and a capacitor. That is, the step-down circuit 811 functions as a voltage regulator for stepping down the first voltage.

Since the second circuit 81 includes the step-down circuit 811, the second voltage having a relatively high voltage value can be supplied to the step-down circuit 811 through the first through electrode 30, and the first voltage stepped down to a relatively low voltage value in the step-down circuit 811 can be supplied to the logic chip 20. Thus, a current flowing through the first through electrodes 30 decreases in proportion to the voltage conversion ratio of the step-down circuit 811, and the reliability of the first through electrode 30 can be maintained even if the total number of the first through electrodes 30 is reduced. Furthermore, since the voltage value can be controlled by the step-down circuit 811 so as to become a voltage necessary for the operation of the logic chip 20, the first voltage having a voltage value necessary for the operation of the logic chip 20 can be supplied. That is, the voltage value necessary for the operation of the logic chip 20 can be ensured even if the number of the first through electrodes 30 arranged in the memory chips 11 among the first through electrodes 30 provided for supplying power to the logic chip 20 is reduced. Thus, the storage capacity of the memory chips 11 can be increased while the voltage value necessary for the operation of the logic chip 20 is ensured.

The second layer 80 may further include a fourth support substrate 82 for supporting the step-down circuit 811. In the example shown in FIG. 9, the step-down circuit 811 is disposed in a recess 821 of the fourth support substrate 82 while being fixed by an adhesive layer 87 and a resin member 88. Thus, the step-down circuit 811 can be firmly fixed at a desired position. However, the position of the step-down circuit 811 is not limited to the above.

The second circuit 81 can include a second interconnect 812. In the example shown in FIG. 9, the second interconnect 812 is disposed in a redistribution layer 83 located on the -Z direction side of the fourth support substrate 82.

One or more second interconnects 812 are provided in the second circuit 81. The first through electrode 30, the step-down circuit 811, and the logic chip 20 are connected in series via the second interconnect 812. Further, the second circuit 81 may be provided with a plurality of second interconnects 812. By electrically connecting the first through electrode 30 and the logic chip 20 via the plurality of second interconnects 812, the number of power supply paths to the logic chip 20 in the second circuit 81 can be increased. Thus, the resistance in the power supply path to the logic chip 20 can be reduced. As a result, the voltage drop between the first through electrode 30 and the logic chip 20 can be reduced, and the possibility that the voltage required for the operation of the logic chip 20 cannot be ensured can be further reduced. When the plurality of second interconnects 812 are provided, the step-down circuit 811 is electrically connected to at least one of the plurality of second interconnects 812.

The second interconnects 812 can electrically connect the first through electrode 30 and the capacitive element 411 of the first layer 40. When the first layer 40 is omitted, the second interconnects 812 can electrically connect the first through electrode 30 and the logic chip 20. In the example shown in FIG. 9, the second interconnects 812 are electrically connected to the capacitive element 411 via an eighth through electrode 813 penetrating the fourth support substrate 82 in the Z-axis direction.

The method of manufacturing the semiconductor device 1A according to the second embodiment may be the same as the method of manufacturing the semiconductor device 1 according to the first embodiment except that the second layer 80 including the step-down circuit 811 is prepared and the second layer 80 is disposed between the stacked structure 10 and the logic chip 20 in the Z-axis direction.

Further, the present invention is not limited to these embodiments, but various variations and modifications may be made without departing from the scope of the present invention.

What is claimed is:

1. A semiconductor device comprising:
a stacked structure including a plurality of stacked memory chips;
a logic chip disposed above the stacked structure and configured to transmit signals to and receive signals from the plurality of memory chips;
a first through electrode configured to supply electric power to the logic chip, the first through electrode penetrating the stacked structure and being electrically connected to the logic chip; and
at least one of a first layer or a second layer disposed between the stacked structure and the logic chip,
wherein the first layer, when present, is connected between the first through electrode and the logic chip, and includes a first circuit including a capacitive element configured to smooth voltage supplied to the logic chip via the first through electrode; and
wherein the second layer, when present, is connected between the first through electrode and the logic chip, and includes a second circuit including a step-down circuit configured to step down the voltage.

2. The semiconductor device according to claim 1, comprising both the first layer and the second layer.

3. The semiconductor device according to claim 1, comprising the first layer, wherein:
the first circuit further includes a plurality of first interconnects electrically connecting the first through electrode and the logic chip; and
at least one of the plurality of first interconnects is electrically connected to the capacitive element.

4. The semiconductor device according to claim 1, comprising the second layer, wherein:
the second circuit further includes a plurality of second interconnects electrically connecting the first through electrode and the logic chip; and
at least one of the plurality of second interconnects is electrically connected to the capacitive element.

5. The semiconductor device according to claim 1, further comprising a third layer disposed between the stacked structure and the logic chip, wherein the third layer includes a third interconnect electrically connecting the first through electrode and the logic chip.

6. The semiconductor device according to claim 1, further comprising a substrate disposed below the stacked structure, wherein the logic chip is separated from the substrate by the stacked structure.

7. The semiconductor device according to claim 1, wherein:
the stacked structure further includes a first support substrate configured to support the plurality of memory chips;
the first support substrate includes a recess and a lateral wall, the lateral wall being located outside the recess;
the plurality of memory chips are disposed within the recess; and
the first through electrode penetrates the lateral wall.

8. The semiconductor device according to claim 7, wherein the first support substrate includes an inorganic material containing silicon.

9. The semiconductor device according to claim 1, further comprising a second support substrate configured to support the logic chip and having a recess in which the logic chip is disposed.

10. The semiconductor device according to claim 9, further comprising a second through electrode and a third through electrode forming at least part of a signal line between the plurality of memory chips and the logic chip, wherein:
the second through electrode penetrates the memory chips; and
the third through electrode is electrically connected to the second through electrode, and electrically connected to the logic chip penetrating the second support substrate.
